(19) United States
(12) Patent Application Publication
(10) Pub. No.: US 2025/0070022 A1
(43) Pub. Date: Feb. 27, 2025

(54) SEMICONDUCTOR DEVICE

(71) Applicant: Samsung Electronics Co., Ltd., Suwon-si (KR)

(72) Inventors: Dongkyun LEE, Suwon-si (KR); Hyejin KIM, Suwon-si (KR); Yonghyeok SON, Suwon-si (KR); Jichang SIM, Suwon-si (KR); Joo-Sung LEE, Suwon-si (KR); Yujin CHO, Suwon-si (KR)

(73) Assignee: Samsung Electronics Co., Ltd., Suwon-si (KR)

(21) Appl. No.: 18/634,325

(22) Filed: Apr. 12, 2024

(30) Foreign Application Priority Data
Aug. 21, 2023 (KR) 10-2023-0109150

(51) Int. Cl. H01L 23/528; H01L 23/522; H10B 12/00

(52) U.S. Cl. CPC H01L 23/5283; H01L 23/5226; H10B 12/315; H10B 12/482; H10B 12/485; H10B 12/488; H10B 12/50

(57) ABSTRACT

A semiconductor device may include a substrate including a cell array region, a core region, and a peripheral circuit region, a core circuit wiring on the core region of the substrate, a core signal wiring overlapping the core circuit wiring, and a contact plug between the core circuit wiring and the core signal wiring. The contact plug may connect the core circuit wiring to the core signal wiring. A positional relationship between the core signal wiring and the contact plug may be different depending on distance from the peripheral circuit region.

### CROSS-REFERENCE TO RELATED APPLICATION

This application claims priority to and the benefit of Korean Patent Application No. 10-2023-0109150, filed in the Korean Intellectual Property Office on Aug. 21, 2023, the entire contents of which is incorporated herein by reference.

### BACKGROUND

### 1. Field

The present disclosure relates to a semiconductor device.

### 2. Description of the Related Art

A semiconductor is a material belonging to an intermediate region between a conductor and an insulator, and refers to a material that may conduct electricity under a specific condition. Various semiconductor devices can be manufactured by using such a semiconductor material, and for example, a memory device and the like can be manufactured. Such a semiconductor device may be used in various electronic devices.

In accordance with miniaturization and high integration trends of electronic devices, it may be necessary to finely form patterns constituting a semiconductor device. As widths of these fine patterns gradually decrease, process difficulty may increase and defect rates of semiconductor devices may increase.

### SUMMARY

The present disclosure attempts to provide a semiconductor device in which wirings positioned in different layers are stably connected.

According to an example embodiment, a semiconductor device may include a substrate including a cell array region, a core region, and a peripheral circuit region, a core circuit wiring on the core region of the substrate, a core signal wiring overlapping the core circuit wiring, and a contact plug MC between the core circuit wiring and the core signal wiring and connecting the core circuit wiring to the core signal wiring. A positional relationship between the core signal wiring and the contact plug may be different depending on distance from the peripheral circuit region.

According to an example embodiment, a semiconductor device may include a substrate including a peripheral circuit region, a plurality of cell array regions at both sides of the peripheral circuit region and arranged along a first direction and a second direction, and a core region between the plurality of cell array regions; a core circuit wiring on the core region of the substrate; a core signal wiring overlapping the core circuit wiring; and a contact plug between the core circuit wiring and the core signal wiring and connecting the core circuit wiring to the core signal wiring. A first distance from a first edge of the core signal wiring to the contact plug may gradually change as a distance of the contact plug from the peripheral circuit region increases.

According to an example embodiment, a semiconductor device may include a substrate including a cell array region, a core region, and a peripheral circuit region; a memory cell on the cell array region of the substrate; a gate stack on the core region of the substrate, the substrate including an impurity region positioned at both sides of the gate stack; a core circuit wiring connected to the impurity region; an insulation layer on the core circuit wiring; a core signal wiring on the insulation layer; and a contact plug penetrating the insulation layer and between the core circuit wiring and the core signal wiring. The contact plug may connects the core circuiting wiring to the core signal wiring. A positional relationship between the core signal wiring and the contact plug may be different depending on a distance of the contact plug from the peripheral circuit region.

According to embodiments, wirings positioned in different layers may be stably connected in a semiconductor device.

### BRIEF DESCRIPTION OF THE DRAWINGS

FIG. 1 is a top plan view showing a semiconductor device according to an embodiment.

FIG. 2 is a top plan view showing a partial region of a semiconductor device according to an embodiment.

FIG. 3 is a cross-sectional view taken along lines A-A′, B-B′, and C-C′ of FIG. 2.

FIG. 4A to FIG. 13B are enlarged plan views or cross-sectional views showing partial regions of a semiconductor device according to an embodiment.

FIG. 14A to FIG. 15B are enlarged plan views or cross-sectional views showing of partial regions of a semiconductor device according to reference example.

FIG. 16 and FIG. 17 is a graph showing misalignment trends between a core circuit wiring and a contact plug in a semiconductor device according to reference example.

### DETAILED DESCRIPTION

Embodiments of inventive concepts will be described more fully hereinafter with reference to the accompanying drawings, in which some example embodiments are shown. As those skilled in the art would realize, the described embodiments may be modified in various different ways, all without departing from the spirit or scope of inventive concepts.

To clearly describe aspects of inventive concepts, parts that are irrelevant to the description are omitted, and like numerals refer to like or similar constituent elements throughout the specification.

Further, since sizes and thicknesses of constituent members shown in the accompanying drawings are arbitrarily given for better understanding and ease of description, inventive concepts are not limited to the illustrated sizes and thicknesses. In the drawings, the thicknesses of layers, films, panels, regions, etc., are exaggerated for clarity. In the drawings, for better understanding and ease of description, the thicknesses of some layers and areas may be exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

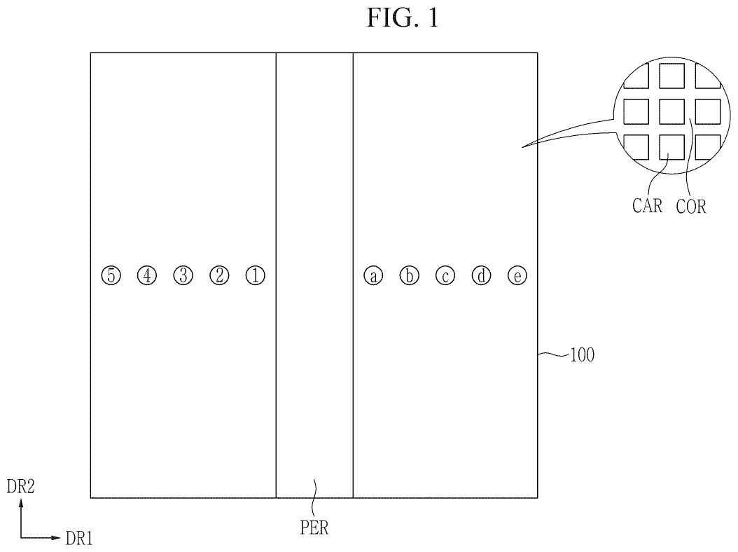

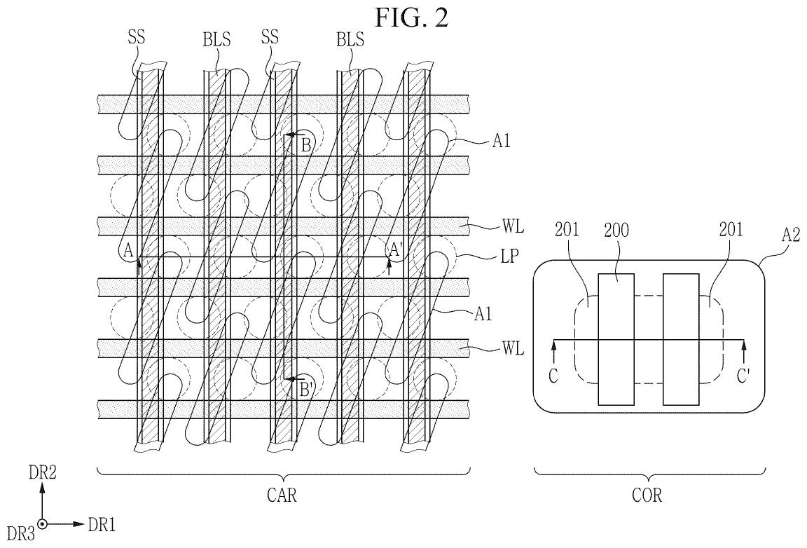

Hereinafter, a semiconductor device according to an embodiment will be described with reference to FIG. 1 to FIG. 13b.

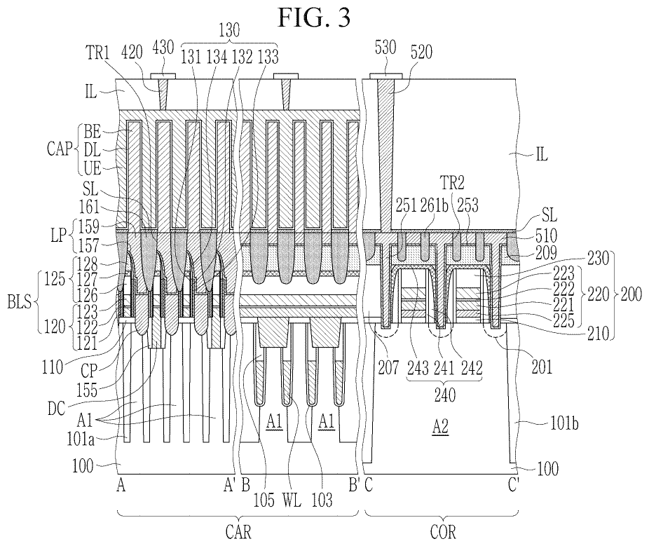

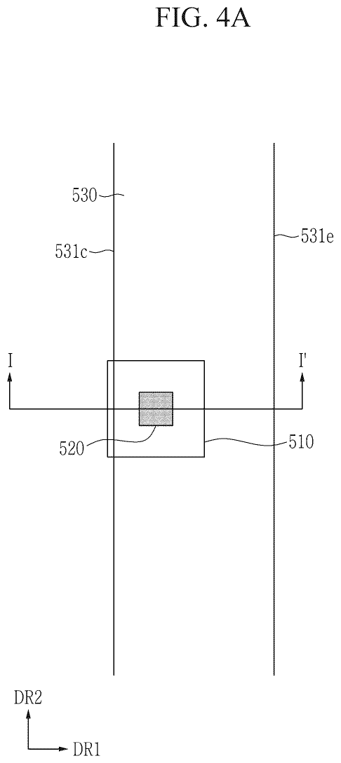

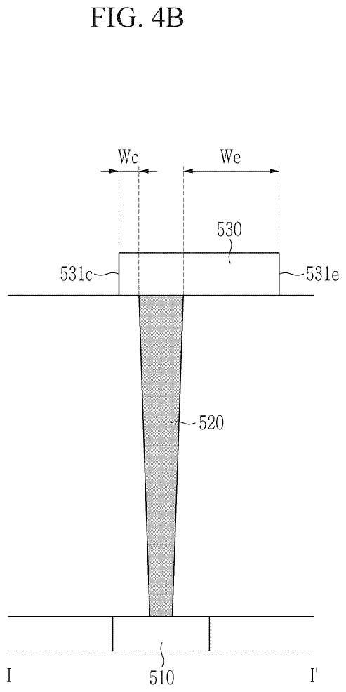

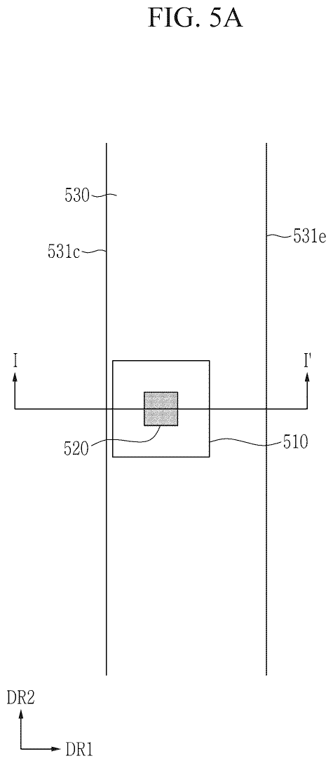

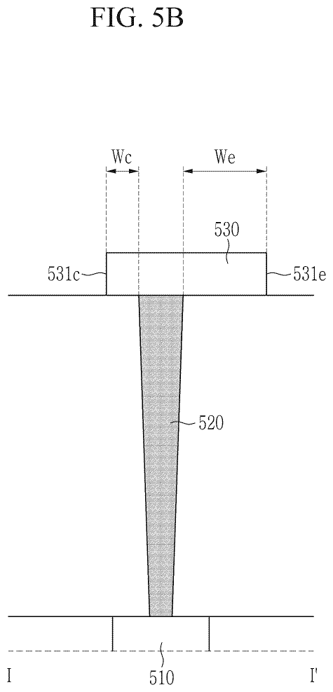

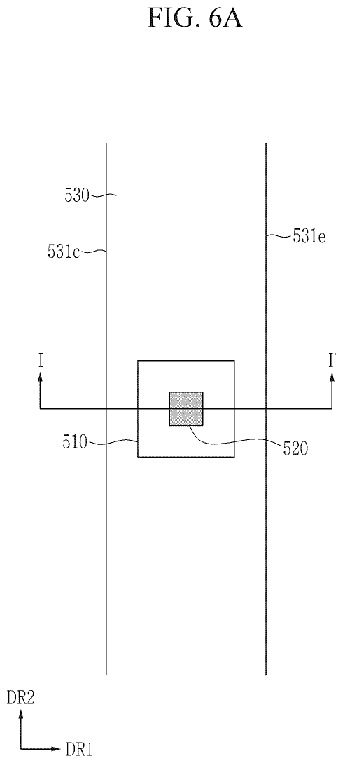

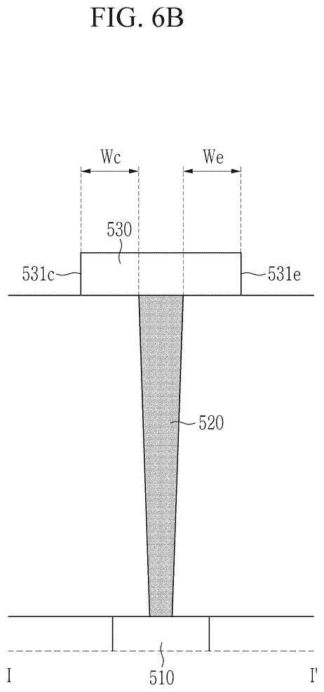

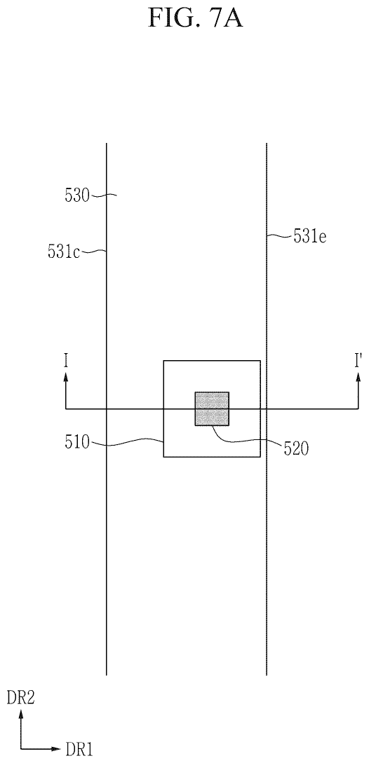

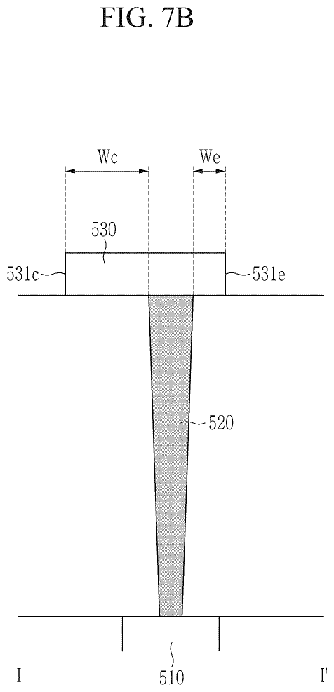

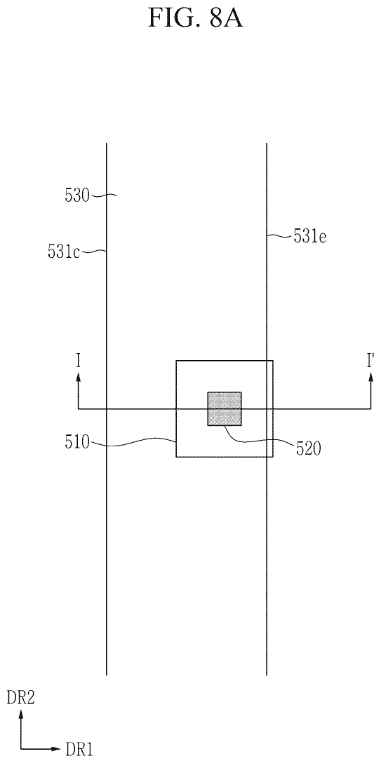

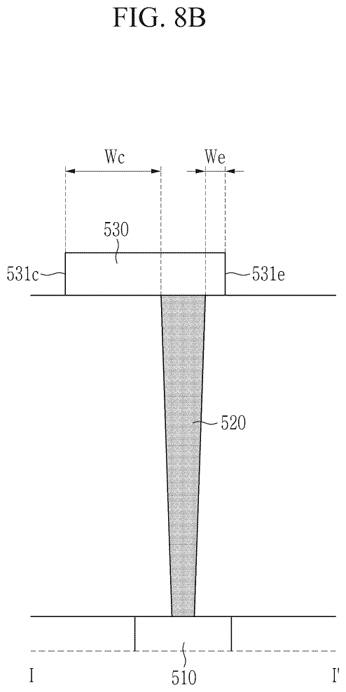

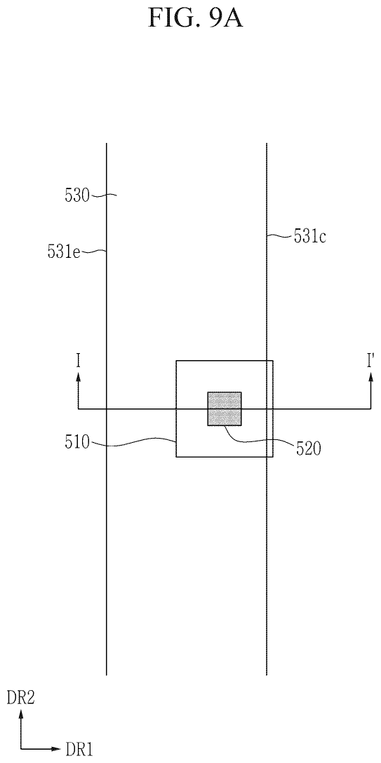

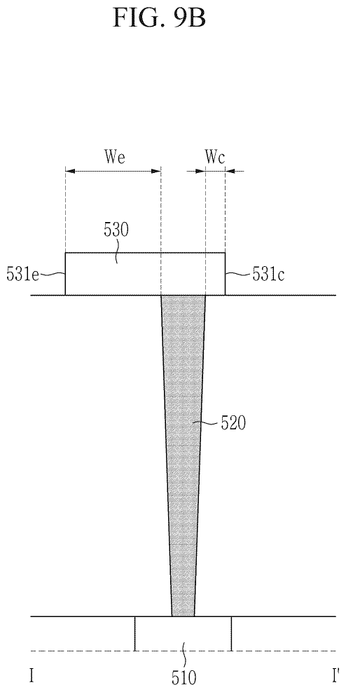

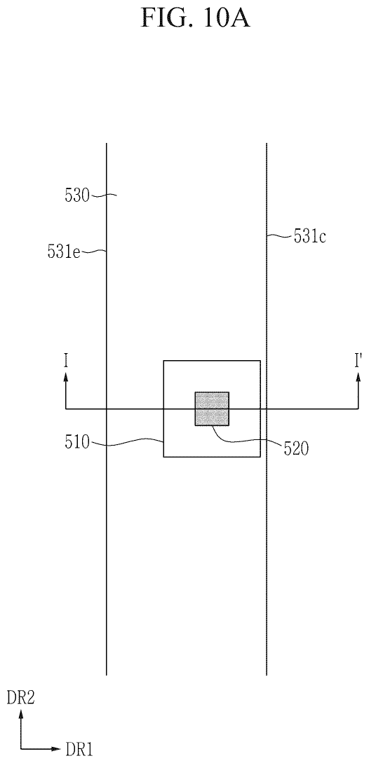

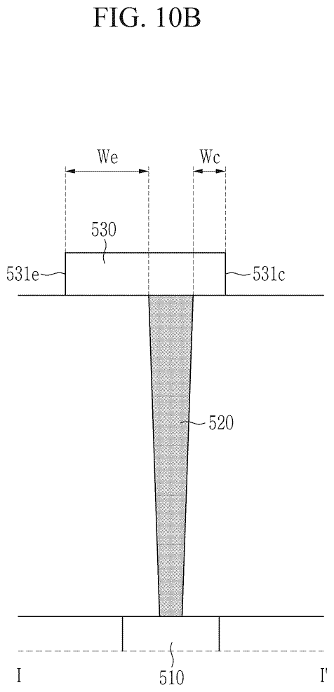

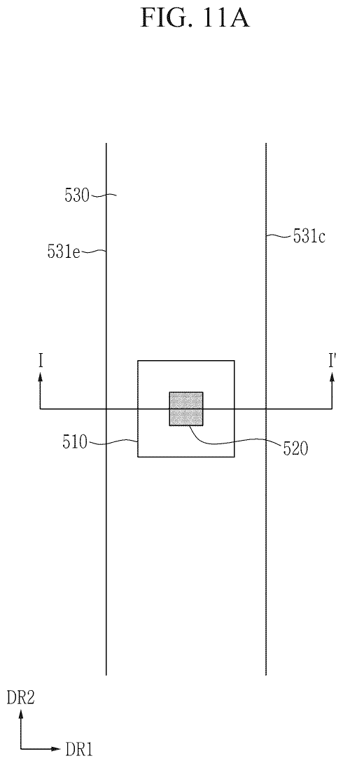

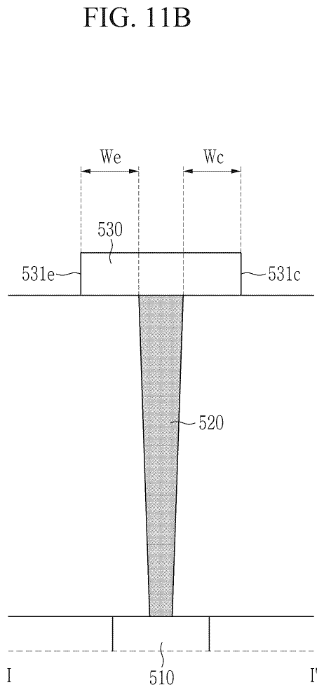

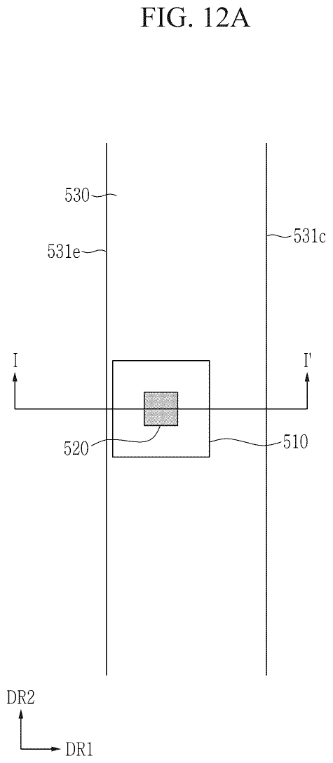

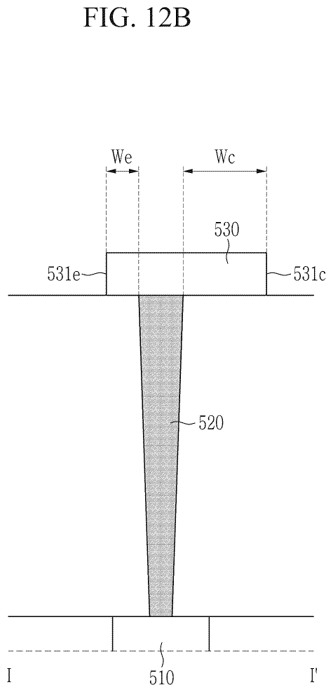

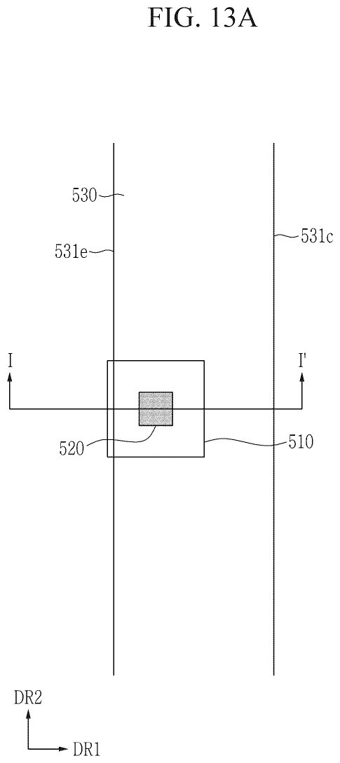

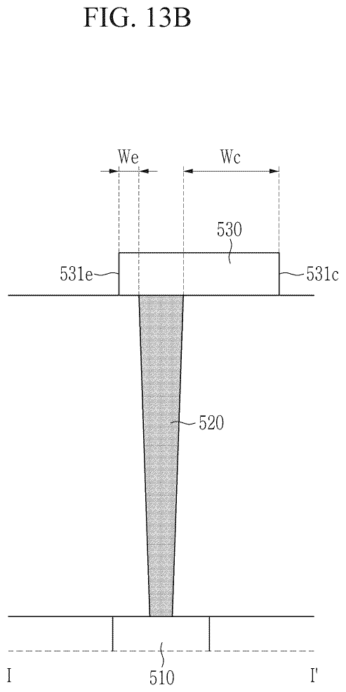

FIG. 1 is a top plan view showing a semiconductor device according to an embodiment. FIG. 2 is a top plan view showing a partial region of a semiconductor device according to an embodiment. FIG. 3 is a cross-sectional view taken along lines A-A′, B-B′, and C-C′ of FIG. 2. FIG. 4A to FIG. 13B are enlarged plan views or cross-sectional views showing partial regions of a semiconductor device according to an embodiment. FIG. 4A, FIG. 5A, FIG. 6A, FIG. 7A, FIG. 8A, FIG. 9A, FIG. 10A, FIG. 11A, FIG. 12A, and FIG. 13A are top plan views. FIG. 4B, FIG. 5B, FIG. 6B, FIG. 7B, FIG. 8B, FIG. 9B, FIG. 10B, FIG. 11B, FIG. 12B, and FIG. 13B are cross-sectional views.

As shown in FIG. 1, a semiconductor device according to an embodiment includes a substrate 100 that includes a cell array region CAR, a core region COR, and a peripheral circuit region PER. One wafer may include a plurality of semiconductor chips, and FIG. 1 shows one semiconductor chip among the plurality of semiconductor chips.

For example, the peripheral circuit region PER may be positioned at a center of a semiconductor device according to an embodiment. A semiconductor chip forming a semiconductor device according to an embodiment may have, in a plan view, a rectangular shape having two sides parallel in a first direction DR1 and two sides parallel in a second direction DR2. The second direction DR2 may cross the first direction DR1. The second direction DR2 may perpendicularly cross the first direction DR1. The peripheral circuit region PER may have, in a plan view, a bar shape extending long along the second direction DR2. Portions positioned on both sides of the peripheral circuit region PER may be separated by the peripheral circuit region PER.

The cell array region CAR and the core region COR may be positioned at the both sides of the peripheral circuit region PER. A plurality of cell array regions CAR may be arranged in the form of a matrix along the first direction DR1 and the second direction DR2. The plurality of cell array regions CAR may be spaced apart from each other, and the core region COR may be positioned between the plurality of cell array regions CAR. Each of the cell array regions CAR may be surrounded by the core region COR. The plurality of cell array regions CAR and the core region COR may be positioned in a portion positioned on a left side of the peripheral circuit region PER, and the plurality of cell array regions CAR and the core region COR may also be positioned in a portion positioned on a right side of the peripheral circuit region PER.

Although the arrangement of the peripheral circuit region PER, the cell array region CAR, and the core region COR has been described above, this is merely an example and is not limited to this and may be changed in various ways.

The plurality of cell array regions CAR each may include memory cell. Each of the cell array regions CAR may include at least one of memory cells of a volatile memory device and memory cells of a non-volatile memory device. For example, cell transistors such as a dynamic random access memory (DRAM), a flash memory, or the like may be positioned in the cell array region CAR. The cell array region CAR may include a plurality of unit memory cells for storing information. One unit memory cell may include at least one transistor and at least one capacitor.

In the core region COR and the peripheral circuit region PER, a driving circuit configured to generate signal to drive a memory cell positioned in the cell array region CAR and wiring configured to transfer such signals may be positioned. For example, a sense amplifier, a write driver, or the like may be positioned in the core region COR. A row decoder, a column decoder, or the like may be positioned in the peripheral circuit region PER.

In a semiconductor device according to an embodiment, wirings to connect the memory cell and the driving circuit, a contact plug to connect between them, or the like may be positioned in the core region COR. Arrangement form of such wirings and the contact plug may be different depending on positions. For example, arrangement form of the wirings and the contact plug at a point close to the peripheral circuit region PER may be different from arrangement form of the wirings and the contact plug at a point far from the peripheral circuit region PER. The arrangement form will be later described in detail.

As shown in FIG. 2 and FIG. 3, a semiconductor device according to an embodiment includes the substrate 100 that includes the cell array region CAR and the core region COR. Although not shown in the drawings, as described above, the substrate 100 may further include a peripheral circuit region.

A first isolation layer 101a defining first active regions A1 may be disposed on the cell array region CAR of the substrate 100. The substrate 100 may be a semiconductor substrate that contains silicon, germanium, or silicon-germanium.

The first active regions A1 may be provided in an upper portion of the substrate 100. The first active regions A1 may be formed by patterning the upper portion of the substrate 100. The first active regions A1 may have a rectangular shape (or bar shape). The first active regions A1 may be 2-dimensionally arranged along the first direction DR1 and the second direction DR2. The first active regions A1 may have a major axis in an oblique direction with respect to the first direction DR1 and the second direction DR2. Each of the first active regions A1 may have its width that narrows as a distance from a bottom surface of the substrate 100 increases in a cross-section. That is, each of the first active regions A1 may have a width that becomes narrower in a direction (e.g., a third direction DR3) perpendicular to an upper surface of the substrate 100.

Word lines WL may be disposed within the substrate 100. The word lines WL may, in a plan view, extend in the first direction DR1, and cross the first active regions A1 and the first isolation layer 101a. The word lines WL may be arranged along the second direction DR2. A gate insulation layer 103 may be interposed between the word lines WL and the substrate 100.

In more detail, gate recess regions may be formed within the first active regions A1 and the first isolation layer 101a. The gate insulation layer 103 may conformally cover an inner sidewall of the gate recess regions. The word lines WL may fill a lower portion of the gate recess regions. The word lines WL may be spaced apart from the first active regions A1 and the first isolation layer 101a interposing the gate insulation layer 103. Upper surfaces of the word lines WL may be positioned below the upper surface of the substrate 100. A gate capping layer 105 may be disposed on an upper surface of the word lines WL, to fill a remaining portion of the gate recess regions. A level of an upper surface of the gate capping layer 105 may substantially the same as a level of the upper surface of the substrate 100.

Bit line structures BLS may, in a plan view, cross the first active regions A1 and extend in the second direction DR2. The bit line structures BLS may cross the word lines WL while being insulated therefrom. The bit line structures BLS may include a bit line capping pattern 125 on a bit line 120 and the bit line 120.

The bit line 120 may include a polysilicon pattern 121, a silicide pattern 122, and a metal pattern 123 that are sequentially stacked. A lower insulation layer 110 may be interposed between the polysilicon pattern 121 and the substrate 100. A bit line contact pattern DC may be positioned between the bit line 120 and the first active region A1. The bit line 120 may be electrically connected to the first active region A1 through the bit line contact pattern DC. A bottom surface of the bit line contact pattern DC may be positioned below the upper surface of the substrate 100, and above an upper surfaces of the word lines WL. The bit line contact pattern DC may be locally disposed within a recess region that is formed within the substrate 100 and exposes an upper surface of the first active region A1. The recess region may have an elliptical shape, in a plan view, and a width in a minor axis direction of the recess region may be larger than a width of the bit line structures BLS.

The bit line capping pattern 125 may be disposed on the metal pattern 123 of the bit line 120. The bit line capping pattern 125 may include a first capping pattern 126, a second capping pattern 127, and a third capping pattern 128 that are sequentially stacked.

A bit line contact spacer 155 may fill the remaining portion of the recess region where the bit line contact pattern DC is formed. For example, the bit line contact spacer 155 may cover both sidewalls of the bit line contact pattern DC. As another example, the bit line contact spacer 155 may surround side surfaces of the bit line contact pattern DC within the recess region. The bit line contact spacer 155 may be formed of an insulating material having etching selectivity with respect to the lower insulation layer 110. For example, the bit line contact spacer 155 may include silicon oxide layer, silicon nitride layer, and/or silicon oxynitride layer, and may be made of a multilayered layer. According to embodiments, an upper surface of the bit line contact spacer 155 may be positioned at the substantially same level as an upper surface of the lower insulation layer 110.

Lower contacts CP may be disposed between sidewalls of the bit line structures BLS. The lower contacts CP may be arranged along the first direction DR1 on a sidewall of the bit line structures BLS. Each of the lower contacts CP may, in a plan view, be disposed between the word lines WL and between the bit line structures BLS. Each of the lower contacts CP may be connected to the substrate 100 between adjacent two bit lines 120 among the bit lines 120. The lower contact CP may be electrically connected to the first active region A1 of the substrate 100. The lower contact CP may include, for example, polysilicon doped with impurities.

A lower end of the lower contact CP may be positioned at a lower level than the upper surface of the substrate 100, and may be positioned at a higher level than a lower surface of the bit line contact pattern DC. An upper surface of the lower contact CP may be positioned below a bottom surface of the bit line capping pattern 125 of a bit line structure BLS. The lower contact CP may be insulated from the bit line contact pattern DC by the bit line contact spacer 155.

A landing pad LP may be disposed on the lower contact CP. The landing pad LP may be electrically connected to the first active region A1 of the substrate 100 through the lower contact CP. An upper surface of the landing pad LP may be positioned above upper surfaces of the bit line structures BLS, and a bottom surface of the landing pad LP may be positioned below the upper surfaces of the bit line structures BLS. For example, the bottom surface of the landing pad LP may be positioned below an upper surface of the metal pattern 123 of the bit line 120. The landing pad LP may include a barrier layer 157 and a pad metal pattern 159 that are sequentially stacked. According to embodiments, a contact silicide pattern may be provided between the lower contact CP and the landing pad LP.

A spacer structure 130 may be provided in between the bit line structures BLS and the lower contact CP. The spacer structure 130 may extend in the second direction DR2 along sidewalls of the bit line structures BLS. The spacer structure 130 may include a first spacer 131, a second spacer 132, a third spacer 133 and a fourth spacer 134. The first spacer 131 may be directly disposed on the sidewall of the bit line structures BLS. The second spacer 132 may be disposed between the first spacer 131 and the lower contact CP. The third spacer 133 may be disposed between the second spacer 132 and the lower contact CP. The second spacer 132 may be positioned at between the first spacer 131 and the third spacer 133. The first spacer 131 and the third spacer 133 may include an insulating material having etching selectivity with respect to the lower insulation layer 110.

The second spacer 132 may include an insulating material having lower permittivity than the first spacer 131 and the third spacer 133. For example, the first spacer 131 and the third spacer 133 may include silicon nitride, and the second spacer 132 may include a silicon oxide layer. As another example, the second spacer 132 may include air. That is, the second spacer 132 may be an air spacer defined between sidewalls of the first spacer 131 and the third spacer 133. The fourth spacer 134 may be provided on an upper surface of the second spacer 132 and on an and side surface of the first spacer 131. The fourth spacer 134 may surround a lower portion of the landing pad LP. The fourth spacer 134 may have a ring shape, in a plan view.

An insulation pattern 161 may fill a space between the landing pads LP. The insulation pattern 161 may surround sidewalls of the landing pads LP. As shown in FIG. 3, the insulation pattern 161 may be provided within a first trench TR1 between sidewalls of the landing pads LP. The first trench TR1 may be a node isolation trench that electrically separates the landing pads LP respectively. The landing pads LP may be spaced apart from each other interposing the first trench TR1. The first trench TR1 may have an inner side surface defined by the landing pads LP, the bit line capping patterns 125, and surfaces of the spacer structure 130. For example, the insulation pattern 161 may include silicon nitride.

Capacitors CAP may be provided on the landing pads LP. The capacitors CAP may be electrically connected to the landing pads LP, respectively. Each of the capacitors CAP may include a lower electrode BE, an upper electrode UE, and a dielectric layer DL therebetween. Each of the lower electrode BE and the upper electrode UE may include, for example, one of titanium, titanium, tungsten, copper and aluminum.

The lower electrode BE and the upper electrode UE may include, doped silicon, Ru, RuO, Pt, PtO, Ir, IrO, SRO(SrRuO), BSRO((Ba,Sr)RuO), CRO(CaRuO), BaRuO, La(Sr,Co)O, Ti, TiN, W, WN, Ta, TaN, TiAlN, TiSiN, TaAlN, TaSiN, or a combination thereof. The dielectric layer DL may include, for example, hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate or a combination thereof.

A capacitor contact via 420 penetrating an insulation layer IL and the insulation layer IL and connected to the capacitor CAP may be provided on the capacitor CAP. The capacitor contact via 420 may be connected to the upper electrode UE of the capacitor CAP.

A cell signal wiring 430 may be positioned above the insulation layer IL. The cell signal wiring 430 may be positioned on the capacitor contact via 420, and may be electrically connected to the capacitor contact via 420. The cell signal wiring 430 may be electrically connected to the capacitor CAP through the capacitor contact via 420. The upper electrode UE of the capacitor CAP may receive a desired and/or alternatively predetermined voltage through the cell signal wiring 430.

A gate stack 200 may be disposed on the substrate 100 of the core region COR. The gate stack 200 may extend in a direction parallel to the upper surface of the substrate 100. For example, the gate stack 200 may have a bar shape, in a plan view. The gate stack 200 may be disposed on a second active region A2 formed in the upper portion of the substrate 100. The second active region A2 may be a region doped with n-type or p-type impurities, and may be defined by a second isolation layer 101b.

Impurity regions 201 may be formed in the upper portion of the substrate 100. The impurity regions 201 may include impurities of a conductivity type different from impurities doped in the second active region A2. The impurity regions 201 may be a pair of source region and drain region electrically connected or separated according to a voltage applied to the gate stack 200. The impurity regions 201 may be spaced apart from each other interposing the gate stack 200. Each of the impurity regions 201 may be adjacently positioned to both lateral sides of the gate stack 200. For example, the gate stack 200 and impurity regions may configure a PMOS transistor, and impurity regions may be p-type impurity regions. The impurity regions 201 may include, for example, at least one of boron (B), aluminum (Al), gallium (Ga) and indium (In). As another example, the gate stack 200 and the impurity regions 201 may configure a NMOS transistor, and the impurity regions 201 may be n-type impurity regions. The impurity regions 201 may include, for example, at least one of phosphorus (P), arsenic (As) and antimony (Sb).

The gate stack 200 may include a gate insulation layer 210, a gate electrode 220 and a gate capping pattern 230. The gate insulation layer 210 may be interposed between the upper surface of the substrate 100 and the gate electrode 220. The gate capping pattern 230 may be disposed on an upper surface of the gate electrode 220.

The gate insulation layer 210 may include a dielectric material. According to embodiments, the gate insulation layer 210 may include a first dielectric layer and a second dielectric layer on a first dielectric layer. The first dielectric layer may have a lower permittivity (e.g., dielectric constant) than the second dielectric layer. The first dielectric layer may include, for example, one of a silicon oxide layer and a silicon oxynitride layer. The second dielectric layer may include a high-K material having higher dielectric constant than a silicon oxide layer and/or a silicon oxynitride layer. The second dielectric layer may include, for example, one of oxide, nitride, silicide, oxynitride including one of hafnium (Hf), aluminum (Al), zirconium (Zr), and lanthanum (La).

The gate electrode 220 may include a work function adjustment layer 225, a first conductive layer 221, a second conductive layer 222, and a third conductive layer 223 that are sequentially stacked. The work function adjustment layer 225 may adjust a threshold voltage of a transistor. According to embodiments, the work function adjustment layer 225 may have a thicker thickness than the gate insulation layer 210. The work function adjustment layer 225 may include at least one of a p-type metal layer and a n-type metal layer. The work function adjustment layer 225 may include, for example, at least one of Ti, Ta, Al, Ni, Co, La, Pd, Nb, Mo, Hf, Ir, Ru, Pt, Yb, Dy, Er, Pd, TiAl, HfSiMo, TiN, WN, TaN, RuN, MoN, TiAlN, TaC, TiC, and TaC. The work function adjustment layer 225 may further include, for example, at least one of La/TiN, Mg/TiN, or Sr/TiN.

The first conductive layer 221 may include a semiconductor material doped with impurities. The first conductive layer 221 may include, for example, polysilicon. The first conductive layer 221 may be, for example, doped with p-type dopants.

The second conductive layer 222 may be positioned between the first conductive layer 221 and the third conductive layer 223. The second conductive layer 222 may have a thinner thickness than the first conductive layer 221 and the third conductive layer 223. The second conductive layer 222 may include silicide formed in an interface between the first conductive layer 221 and the third conductive layer 223. The second conductive layer 222 may include, for example, one of titanium silicide, cobalt silicide, nickel silicide, tungsten silicide, platinum silicide and molybdenum silicide.

The third conductive layer 223 may include a metal material. The third conductive layer 223 may include, for example, at least one of W, Ti, or Ta.

The gate capping pattern 230 may be disposed on the upper surface of the gate electrode 220. The gate capping pattern 230 may be formed to cover an upper surface of the third conductive layer 223, to protect the gate electrode 220. The gate capping pattern 230 may include insulating material. The gate capping pattern 230 may include, for example, silicon nitride.

A gate spacer structure 240 may be disposed on side surfaces of the gate stack 200. The gate spacer structure 240 may include a first gate spacer 241, a second gate spacer 242 and a third gate spacer 243.

The first gate spacer 241 may be disposed on a side surface of the gate stack 200. The first gate spacer 241 may vertically extend along the side surfaces of the gate stack 200. The first gate spacer 241 may have a lower oxygen element content ratio than the second gate spacer 242. The first gate spacer 241 may have a first permittivity, and the first permittivity may have a value in the range of 6.5 to 7.5. The first gate spacer 241 may include a material that has etching selectivity with the first dielectric layer 212. The first gate spacer 241 may include, for example, silicon nitride. An upper surface of the first gate spacer 241 may be coplanar with an upper surface of the gate capping pattern 230. The first gate spacer 241 may be directly disposed on a side surface of the gate electrode 220 and a side surface of the gate capping pattern 230.

The second gate spacer 242 may be disposed on the first gate spacer 241. The second gate spacer 242 may have a larger width than the first gate spacer 241. A width of the second gate spacer 242 may decrease away from the upper surface of the substrate 100. The second gate spacer 242 may include, for example, silicon oxide.

The third gate spacer 243 may be provided on the second gate spacer 242. The third gate spacer 243 may extend on an upper surface of the gate stack 200, so as to cover the upper surface of the first gate spacer 241 and the upper surface of the gate capping pattern 230. The third gate spacer 243 may extend on the upper surface of the substrate 100.

A first interlayer insulation layer 207 may be formed on the substrate 100. The first interlayer insulation layer 207 may cover sidewalls of the gate spacer structure 240, and may not cover an upper surface of the gate spacer structure 240. An upper surface of the first interlayer insulation layer 207 may be coplanar with an upper surface of the third gate spacer 243. The first interlayer insulation layer 207 may include a silicon oxide layer formed by HDP oxide layer, or FCVD (flowable CVD) method. A second interlayer insulation layer 209 may be positioned on the first interlayer insulation layer 207. A lower surface of the second interlayer insulation layer 209 may cover the upper surface of the third gate spacer 243. The second interlayer insulation layer 209 may include silicon nitride.

A core circuit wiring 510 may be positioned on the second interlayer insulation layer 209. The core circuit wiring 510 positioned the core region COR may be positioned in the same layer as the pad metal pattern 159 of the landing pad LP positioned in the cell array region CAR. The core circuit wiring 510 may be formed in same process by using the same material as the pad metal pattern 159. The core circuit wiring 510 may be connected to the impurity regions 201 through a contact via 251. The contact via 251 and the core circuit wiring 510 may include, for example, at least one of copper (Cu), tungsten (W) and aluminum (Al), tantalum (Ta) and titanium (Ti). The contact via 251 may penetrate the first interlayer insulation layer 207 and the second interlayer insulation layer 209, to be connected to the substrate 100. According to embodiments, a lower end of the contact via 251 may be positioned at a lower level than the upper surface of the substrate 100. The contact via 251 may electrically connect between the core circuit wiring 510 and the impurity regions 201.

A contact barrier layer 253 may cover surfaces of the core circuit wiring 510 and the contact via 251. The contact barrier layer 253 may be provided on a lower surface of between the core circuit wiring 510 and the second interlayer insulation layer 209. The contact barrier layer 253 may be provided on side surfaces of the contact via 251 and lower surfaces. The contact barrier layer 253 may include metal nitride. The contact barrier layer 253 may include, for example, one of titanium nitride (TiN), tantalum nitride (TaN) and tungsten nitride (WN).

A second trench TR2 may be formed between core circuit wirings 510. The second trench TR2 may be formed between sidewalls of the core circuit wirings 510, and may be formed by a desired and/or alternatively predetermined depth from an upper surface of the second interlayer insulation layer 209. A lower end of the second trench TR2 may be positioned at a higher level than the upper surface of the gate capping pattern 230.

As an example, the second trench TR2 may be disposed on a place vertically overlapping the gate stack 200, or may be disposed on a place vertically overlapping the second isolation layer 101b between the gate stacks 200.

A wiring insulation pattern 261b may fill the second trench TR2. As an example, a wiring insulation pattern 261b may include silicon nitride.

An etch stop layer SL covering the insulation pattern 161, the wiring insulation pattern 261b, and the core circuit wirings 510 may be provided. The insulation layer IL may be provided on the etch stop layer SL. A contact plug 520 may be provided to penetrate the insulation layer IL and the etch stop layer SL, and to be connected to the core circuit wirings 510. The contact plug 520 positioned the core region COR may be positioned in the same layer as the capacitor contact via 420 positioned in the cell array region CAR. The contact plug 520 may be formed in same process by using the same material as the capacitor contact via 420.

A core signal wiring 530 may be positioned above the insulation layer IL. The core signal wiring 530 may be positioned on the contact plug 520, and may be electrically connected to the contact plug 520. The core signal wiring 530 may be electrically connected to the core circuit wiring 510 through the contact plug 520. The core circuit wiring 510 may receive a desired and/or alternatively predetermined signal through the core signal wiring 530. The core signal wiring 530 positioned the core region COR may be positioned in the same layer as the cell signal wiring 430 positioned in the cell array region CAR. The core signal wiring 530 may be formed in same process by using the same material as the cell signal wiring 430.

Hereinafter, the arrangement form of the core circuit wiring 510, the contact plug 520, and the core signal wiring 530 in the core region COR positioned on the right side of the peripheral circuit region PER is described as follows. In the core region COR positioned on the right side of the peripheral circuit region PER, a point \textcircled{b}, a point \textcircled{c}, a point \textcircled{d}, and a point \textcircled{e} may be defined to be gradually away from a point a closest to the peripheral circuit region PER along the first direction DR1. At this time, the point \textcircled{e} may be positioned farthest from the peripheral circuit region PER. The point \textcircled{e} may be positioned in a central portion between the peripheral circuit region PER and a right-side edge of the semiconductor chip.

First, FIG. 4A is a top plan view showing a portion of the core region COR positioned at the point \textcircled{a} closest to the peripheral circuit region PER, in the right side of the peripheral circuit region PER. FIG. 4B is a cross-sectional view along line I-I′ of FIG. 4A. In FIG. 4A and FIG. 4B, a gate stack or the like positioned the core region COR is not illustrated, and the core circuit wiring 510, the contact plug 520, the core signal wiring 530, and the like are schematically shown. In the same way, in FIG. 5A to FIG. 13B, the core circuit wiring 510, the contact plug 520, the core signal wiring 530, and the like are schematically shown.

The core signal wiring 530 may extend long along substantially one direction. For example, the core signal wiring 530 may extend along the second direction DR2. An extension direction of the core signal wiring 530 may be parallel to an extension direction of the peripheral circuit region PER. The core signal wiring 530 may include a first edge 531c and a second edge 531e facing each other. The first edge 531c and the second edge 531e may be parallel to the second direction DR2. At this time, the first edge 531c may be positioned closer to the peripheral circuit region PER than the second edge 531e. The second edge 531e may be positioned farther from the peripheral circuit region PER than the first edge 531c.

The contact plug 520 may overlap the core signal wiring 530. A width of the contact plug 520 may be smaller than a width of the core signal wiring 530. An upper surface of the contact plug 520 may be fully covered by the core signal wiring 530. That is, an entirety of the contact plug 520 may overlap at least a portion of the core signal wiring 530. However, it is not limited thereto, and at least a portion of the contact plug 520 may not overlap the core signal wiring 530.

A first distance Wc from the first edge 531c of the core signal wiring 530 to the contact plug 520 may be smaller than a second distance We from the second edge 531e of the core signal wiring 530 to the contact plug 520. That is, the distance from a left-side edge of the core signal wiring 530 to the contact plug 520 may be smaller than the distance from a right-side edge of the core signal wiring 530 to the contact plug 520.

In a semiconductor device according to an embodiment, a positional relationship between the core signal wiring 530 and the contact plug 520 may be different depending on a distance from the peripheral circuit region PER. For example, the first distance Wc and the second distance We may be different depending on the distance from the peripheral circuit region PER. In the core region COR positioned on the right side of the peripheral circuit region PER, at the point \textcircled{a} closest to the peripheral circuit region PER, the first distance Wc may be smallest, and the second distance We may be largest.

The core circuit wiring 510 may overlap the contact plug 520. The core circuit wiring 510 is illustrated to have a quadrangular shape in a plan view, but is not limited thereto. The core circuit wiring 510 may have other polygonal shapes other than the quadrangular shape, may have a circular shape or an elliptical shape, and may have a bar shape. A width of the core circuit wiring 510 may be larger than the width of the contact plug 520. The contact plug 520 may cover at least a portion of an upper surface of the core circuit wiring 510. The entirety of the contact plug 520 may overlap at least a portion the core circuit wiring 510. The contact plug 520 may overlap a central portion of the core circuit wiring 510. That is, the distance from a first side edge of the core circuit wiring 510 to the contact plug 520 may be substantially the same as the distance from a second side edge of the core circuit wiring 510 to the contact plug 520. However, it is not limited thereto, and the positional relationship between the contact plug 520 the core circuit wiring 510 may be variously changed.

The core circuit wiring 510 may overlap the core signal wiring 530. The core circuit wiring 510 is illustrated to partially overlap the core signal wiring 530, but is not limited thereto. Depending on cases, an entirety of the core circuit wiring 510 may overlap the core signal wiring 530.

Subsequently, FIG. 5A is a top plan view showing a portion of the core region COR at the point \textcircled{b} positioned farther from the peripheral circuit region PER than the point \textcircled{a} in the right side of the peripheral circuit region PER. FIG. 5B is a cross-sectional view along line I-I′ of FIG. 5A.

The core signal wiring 530, the contact plug 520, and shape of the core circuit wiring 510 at the point \textcircled{b} may be substantially the same as the point \textcircled{a}. The positional relationship between the core signal wiring 530 and the contact plug 520 at the point \textcircled{b} may be different as the point \textcircled{a}. The positional relationship between the contact plug 520 and the core circuit wiring 510 at the point \textcircled{b} may be substantially the same as the point \textcircled{a}.

The first distance Wc from the first edge 531c of the core signal wiring 530 to the contact plug 520 at the point \textcircled{b} may be smaller than the second distance We from the second edge 531e of the core signal wiring 530 to the contact plug 520. That is, the distance from the left-side edge of the core signal wiring 530 to the contact plug 520 may be smaller than the distance from the right-side edge of the core signal wiring 530 to the contact plug 520. A difference between the first distance Wc and the second distance We at the point \textcircled{b} may be smaller than a difference between the first distance Wc and the second distance We at the point \textcircled{a}.

In a semiconductor device according to an embodiment, the positional relationship between the core signal wiring 530 and the contact plug 520 may be different depending on the distance from the peripheral circuit region PER. The first distance Wc at the point \textcircled{b} relatively farther from the peripheral circuit region PER than the point \textcircled{a} in the core region COR positioned on the right side of the peripheral circuit region PER may be larger than the first distance Wc at the point \textcircled{a}. The second distance We at the point \textcircled{b} may be smaller than the second distance We at the point \textcircled{a}.

The contact plug 520 may overlap the central portion of the core circuit wiring 510. That is, the distance from the first side edge of the core circuit wiring 510 to the contact plug 520 may be substantially the same as the distance from the second side edge of the core circuit wiring 510 to the contact plug 520.

Subsequently, FIG. 6A is a top plan view showing a portion of the core region COR at the point \textcircled{c} positioned farther from the peripheral circuit region PER than the point \textcircled{b} in the right side of the peripheral circuit region PER. FIG. 6B is a cross-sectional view along line I-I′ of FIG. 6A. The point \textcircled{c} may be a center point between the point \textcircled{a} and the point \textcircled{e}. The point \textcircled{c} may be a center point between a closest point to the peripheral circuit region PER and a farthest point from the peripheral circuit region PER. The point \textcircled{c} may be a center point between a right-side edge of the peripheral circuit region PER and a right-side edge of the semiconductor chip.

The first distance Wc from the first edge 531c of the core signal wiring 530 to the contact plug 520 at the point \textcircled{c} may be substantially the same as the second distance We from the second edge 531e of the core signal wiring 530 to the contact plug 520. That is, the distance from the left-side edge of the core signal wiring 530 to the contact plug 520 may be substantially the same as the distance from the right-side edge of the core signal wiring 530 to the contact plug 520. A difference between the first distance Wc and the second distance We at the point \textcircled{c} may be smaller than the difference between the first distance Wc and the second distance We at the point \textcircled{b}.

In a semiconductor device according to an embodiment, the positional relationship between the core signal wiring 530 and the contact plug 520 may be different depending on the distance from the peripheral circuit region PER. The first distance Wc at the point \textcircled{c} relatively farther from the peripheral circuit region PER than the point \textcircled{b} in the core region COR positioned on the right side of the peripheral circuit region PER may be larger than the first distance Wc at the point \textcircled{b}. The second distance We at the point \textcircled{c} may be smaller than the second distance We at the point \textcircled{b}.

The contact plug 520 may overlap the central portion of the core circuit wiring 510. That is, the distance from the first side edge of the core circuit wiring 510 to the contact plug 520 may be substantially the same as the distance from the second side edge of the core circuit wiring 510 to the contact plug 520.

Subsequently, FIG. 7A is a top plan view showing a portion of the core region COR at the point \textcircled{d} positioned farther than the point \textcircled{c} from the peripheral circuit region PER, in the right side of the peripheral circuit region PER. FIG. 7B is a cross-sectional view along line I-I′ of FIG. 7A.

The first distance Wc from the first edge 531c of the core signal wiring 530 to the contact plug 520 at the point \textcircled{d} may be greater than the second distance We from the second edge 531e of the core signal wiring 530 to the contact plug 520. That is, the distance from the left-side edge of the core signal wiring 530 to the contact plug 520 may be greater than the distance from the right-side edge of the core signal wiring 530 to the contact plug 520. A difference between the first distance Wc and the second distance We at the point \textcircled{d} may be greater than the difference between the first distance Wc and the second distance We at the point \textcircled{c}.

In a semiconductor device according to an embodiment, the positional relationship between the core signal wiring 530 and the contact plug 520 may be different depending on the distance from the peripheral circuit region PER. The first distance Wc at the point \textcircled{d} relatively farther from the peripheral circuit region PER than the point \textcircled{c} in the core region COR positioned on the right side of the peripheral circuit region PER may be greater than the first distance Wc at the point \textcircled{c}. The second distance We at the point \textcircled{d} may be smaller than the second distance We at the point \textcircled{c}.

The contact plug 520 may overlap the central portion of the core circuit wiring 510. That is, the distance from the first side edge of the core circuit wiring 510 to the contact plug 520 may be substantially the same as the distance from the second side edge of the core circuit wiring 510 to the contact plug 520.

Subsequently, FIG. 8A is a top plan view showing a portion the core region COR at the point \textcircled{e} farthest from the peripheral circuit region PER, in the right side of the peripheral circuit region PER. FIG. 8B is a cross-sectional view along line I-I′ of FIG. 8A.

The first distance Wc from the first edge 531c of the core signal wiring 530 to the contact plug 520 at the point \textcircled{e} may be greater than the second distance We from the second edge 531e of the core signal wiring 530 to the contact plug 520. That is, the distance from the left-side edge of the core signal wiring 530 to the contact plug 520 may be greater than the distance from the right-side edge of the core signal wiring 530 to the contact plug 520. A difference between the first distance Wc and the second distance We at the point \textcircled{e} may be greater than the difference between the first distance Wc and the second distance We at the point \textcircled{d}.

In a semiconductor device according to an embodiment, the positional relationship between the core signal wiring 530 and the contact plug 520 may be different depending on the distance from the peripheral circuit region PER. The first distance Wc at the point \textcircled{e} relatively farther from the peripheral circuit region PER than the point \textcircled{d} in the core region COR positioned on the right side of the peripheral circuit region PER may be greater than the first distance Wc at the point \textcircled{d}. The second distance We at the point \textcircled{e} may be smaller than the second distance We at the point \textcircled{d}.

The contact plug 520 may overlap the central portion of the core circuit wiring 510. That is, the distance from the first side edge of the core circuit wiring 510 to the contact plug 520 may be substantially the same as the distance from the second side edge of the core circuit wiring 510 to the contact plug 520.

Hereinafter, the arrangement form of the core circuit wiring 510, the contact plug 520, and the core signal wiring 530 in the core region COR positioned on the left side of the peripheral circuit region PER is described as follows. In a region positioned on the left side of the peripheral circuit region PER, along an opposite direction of along the first direction DR1 from a point \textcircled{1} closest to the peripheral circuit region PER, a point \textcircled{2}point \textcircled{3}, a point \textcircled{4}, and a point \textcircled{5} may be defined to be gradually away from the peripheral circuit region PER. At this time, the point \textcircled{5} may be positioned farthest from the peripheral circuit region PER. The point \textcircled{3} may be positioned in a central portion between the peripheral circuit region PER and a left-side edge of the semiconductor chip.

First, FIG. 9A is a top plan view showing a portion of the core region COR positioned at the point \textcircled{1} closest to the peripheral circuit region PER, in the left side of the peripheral circuit region PER. FIG. 9B is a cross-sectional view along line I-I′ of FIG. 9A.

The core signal wiring 530 may extend long along substantially one direction. For example, the core signal wiring 530 may extend along the second direction DR2. The extension direction of the core signal wiring 530 may be parallel to the extension direction of the peripheral circuit region PER. The core signal wiring 530 may include the first edge 531c and the second edge 531e facing each other. The first edge 531c and the second edge 531e may be parallel to the second direction DR2. At this time, the first edge 531c may be positioned closer to the peripheral circuit region PER than the second edge 531e. The second edge 531e may be positioned farther from the peripheral circuit region PER than the first edge 531c.

The contact plug 520 may overlap the core signal wiring 530. The width of the contact plug 520 may be smaller than the width of the core signal wiring 530. The upper surface of the contact plug 520 may be fully covered by the core signal wiring 530. That is, the entirety of the contact plug 520 may overlap at least a portion of the core signal wiring 530. However, it is not limited thereto, and at least a portion of the contact plug 520 may not overlap the core signal wiring 530.

The first distance Wc from the first edge 531c of the core signal wiring 530 to the contact plug 520 may be smaller than the second distance We from the second edge 531e of the core signal wiring 530 to the contact plug 520. That is, the distance from the right-side edge of the core signal wiring 530 to the contact plug 520 may be smaller than the distance from the left-side edge of the core signal wiring 530 to the contact plug 520.

In a semiconductor device according to an embodiment, the positional relationship between the core signal wiring 530 and the contact plug 520 may be different depending on the distance from the peripheral circuit region PER. For example, the first distance Wc and the second distance We may be different depending on the distance from the peripheral circuit region PER. In the core region COR positioned on the left side of the peripheral circuit region PER, at the point \textcircled{1} closest to the peripheral circuit region PER, the first distance Wc may be smallest, and the second distance We may be largest.

The contact plug 520 may overlap the central portion of the core circuit wiring 510. That is, the distance from the first side edge of the core circuit wiring 510 to the contact plug 520 may be substantially the same as the distance from the second side edge of the core circuit wiring 510 to the contact plug 520.

Subsequently, FIG. 10A is a top plan view showing a portion of the core region COR at the point \textcircled{2} positioned farther than the point \textcircled{1} from the peripheral circuit region PER, in the left side of the peripheral circuit region PER. FIG. 10B is a cross-sectional view along line I-I′ of FIG. 10A.

The core signal wiring 530, the contact plug 520, and shape of the core circuit wiring 510 at the point \textcircled{2} may be substantially the same as the point \textcircled{1}. The positional relationship between the core signal wiring 530 and the contact plug 520 at the point \textcircled{2} may be different as the point \textcircled{1}. The positional relationship between the contact plug 520 and the core circuit wiring 510 at the point \textcircled{2} may be substantially the same as the point \textcircled{1}.

The first distance Wc from the first edge 531c of the core signal wiring 530 to the contact plug 520 at the point \textcircled{2} may be smaller than the second distance We from the second edge 531e of the core signal wiring 530 to the contact plug 520. That is, the distance from the right-side edge of the core signal wiring 530 to the contact plug 520 may be smaller than the distance from the left-side edge of the core signal wiring 530 to the contact plug 520. A difference between the first distance Wc and the second distance We at the point \textcircled{2} may be smaller than difference between the first distance Wc and the second distance We at the point \textcircled{1}.

In a semiconductor device according to an embodiment, the positional relationship between the core signal wiring 530 and the contact plug 520 may be different depending on the distance from the peripheral circuit region PER. The first distance Wc at the point \textcircled{2} relatively farther from the peripheral circuit region PER than the point \textcircled{1} in the core region COR positioned on the left side of the peripheral circuit region PER may be greater than the first distance Wc at the point \textcircled{1}. The second distance We at the point \textcircled{2} may be smaller than the second distance We at the point \textcircled{1}.

The contact plug 520 may overlap the central portion of the core circuit wiring 510. That is, the distance from the first side edge of the core circuit wiring 510 to the contact plug 520 may be substantially the same as the distance from the second side edge of the core circuit wiring 510 to the contact plug 520.

Subsequently, FIG. 11A is a top plan view showing a portion of the core region COR at the point \textcircled{3} positioned farther than the point \textcircled{2} from the peripheral circuit region PER, in the left side of the peripheral circuit region PER. FIG. 11B is a cross-sectional view along line I-I′ of FIG. 11A. The point \textcircled{3} may be a center point between the point \textcircled{1} and the point \textcircled{5}. The point \textcircled{3} may be a center point between the closest point to the peripheral circuit region PER and the farthest point from the peripheral circuit region PER. The point \textcircled{3} may be a center point between a left-side edge of the peripheral circuit region PER and a left-side edge of the semiconductor chip.

The first distance Wc from the first edge 531c of the core signal wiring 530 to the contact plug 520 at the point \textcircled{3} may be substantially the same as the second distance We from the second edge 531e of the core signal wiring 530 to the contact plug 520. That is, the distance from the right-side edge of the core signal wiring 530 to the contact plug 520 may be substantially the same as the distance from the left-side edge of the core signal wiring 530 to the contact plug 520. A difference between the first distance Wc and the second distance We at the point \textcircled{3} may be smaller than the difference between the first distance Wc and the second distance We at the point \textcircled{2}.

In a semiconductor device according to an embodiment, the positional relationship between the core signal wiring 530 and the contact plug 520 may be different depending on the distance from the peripheral circuit region PER. The first distance Wc at the point \textcircled{3} relatively farther than the point \textcircled{2} from the peripheral circuit region PER, in the core region COR positioned on the left side of the peripheral circuit region PER may be larger than the first distance Wc at the point \textcircled{2}. The second distance We at the point \textcircled{3} may be smaller than the second distance We at the point \textcircled{2}.

The contact plug 520 may overlap the central portion of the core circuit wiring 510. That is, the distance from the first side edge of the core circuit wiring 510 to the contact plug 520 may be substantially the same as the distance from the second side edge of the core circuit wiring 510 to the contact plug 520.

Subsequently, FIG. 12A is a top plan view showing a portion of the core region COR at the point \textcircled{4} positioned farther than the point \textcircled{3} from the peripheral circuit region PER, in the left side of the peripheral circuit region PER. FIG. 12B is a cross-sectional view along line I-I′ of FIG. 12A.

The first distance Wc from the first edge 531c of the core signal wiring 530 to the contact plug 520 at the point \textcircled{4} may be greater than the second distance We from the second edge 531e of the core signal wiring 530 to the contact plug 520. That is, the distance from the right-side edge of the core signal wiring 530 to the contact plug 520 may be greater than the distance from the left-side edge of the core signal wiring 530 to the contact plug 520. A difference between the first distance Wc and the second distance We at the point \textcircled{4} may be greater than the difference between the first distance Wc and the second distance We at the point \textcircled{3}.

In a semiconductor device according to an embodiment, the positional relationship between the core signal wiring 530 and the contact plug 520 may be different depending on the distance from the peripheral circuit region PER. The first distance Wc at the point \textcircled{4} relatively farther from the peripheral circuit region PER than the point \textcircled{3} in the core region COR positioned on the left side of the peripheral circuit region PER may be greater than the first distance Wc at the point \textcircled{3}. The second distance We at the point \textcircled{4} may be smaller than the second distance We at the point \textcircled{3}.

The contact plug 520 may overlap the central portion of the core circuit wiring 510. That is, the distance from the first side edge of the core circuit wiring 510 to the contact plug 520 may be substantially the same as the distance from the second side edge of the core circuit wiring 510 to the contact plug 520.

Subsequently, FIG. 13A is a top plan view showing a portion the core region COR at the point \textcircled{5} farthest from the peripheral circuit region PER, in the left side of the peripheral circuit region PER. FIG. 13B is a cross-sectional view along line I-I′ of FIG. 13A.

The first distance Wc from the first edge 531c of the core signal wiring 530 to the contact plug 520 at the point \textcircled{5} may be greater than the second distance We from the second edge 531e of the core signal wiring 530 to the contact plug 520. That is, the distance from the right-side edge of the core signal wiring 530 to the contact plug 520 may be greater than the distance from the left-side edge of the core signal wiring 530 to the contact plug 520. A difference between the first distance Wc and the second distance We at the point \textcircled{5} may be greater than the difference between the first distance Wc and the second distance We at the point \textcircled{4}.

In a semiconductor device according to an embodiment, the positional relationship between the core signal wiring 530 and the contact plug 520 may be different depending on the distance from the peripheral circuit region PER. The first distance Wc at the point \textcircled{5} relatively farther from the peripheral circuit region PER than the point \textcircled{4} in the core region COR positioned on the left side of the peripheral circuit region PER may be greater than the first distance Wc at the point \textcircled{4}. The second distance We at the point \textcircled{5} may be smaller than the second distance We at the point \textcircled{4}.

The contact plug 520 may overlap the central portion of the core circuit wiring 510. That is, the distance from the first side edge of the core circuit wiring 510 to the contact plug 520 may be substantially the same as the distance from the second side edge of the core circuit wiring 510 to the contact plug 520.

A plurality of core signal wirings 530, a plurality of contact plugs 520, and a plurality of core circuit wirings 510 may be positioned at the core region COR of a semiconductor device according to an embodiment. Each of the core signal wirings 530 may be connected to the core circuit wiring 510 through the contact plug 520. As discussed above, the positional relationship between the core signal wiring 530 and the contact plug 520 in the core region COR close to the peripheral circuit region PER may be different from the positional relationship between the core signal wiring 530 and the contact plug 520 in the core region COR far from the peripheral circuit region PER. That is, the positional relationship between the core signal wiring 530 and the contact plug 520 may be different depending on distance from the peripheral circuit region PER. The first distance Wc from the first edge 531c of the core signal wiring 530 to the contact plug 520 may gradually increase as a distance from the peripheral circuit region PER increases. In addition, the second distance We from the second edge 531e of the core signal wiring 530 to the contact plug 520 may gradually decrease as a distance from the peripheral circuit region PER increases. At this time, the first edge 531c may be positioned closer to the peripheral circuit region PER than the second edge 531e. At the first distance Wc at the closest point to the peripheral circuit region PER may be smaller than the second distance We. The first distance Wc at the farthest point from the peripheral circuit region PER may be greater than the second distance We. At a center point between the closest point to the peripheral circuit region PER and the farthest point from the peripheral circuit region PER, the first distance Wc and the second distance We may be substantially the same.

As for the core region COR positioned on the right side of the peripheral circuit region PER, the distance from the left-side edge of the core signal wiring 530 to the contact plug 520 may gradually increase as a distance from the peripheral circuit region PER increases. In addition, the distance from the right-side edge of the core signal wiring 530 to the contact plug 520 may gradually decrease as a distance from the peripheral circuit region PER increases. At the closest point to the peripheral circuit region PER among the core region COR positioned on the right side of the peripheral circuit region PER, the distance from the left-side edge of the core signal wiring 530 to the contact plug 520 may be smaller than the distance from the right-side edge of the core signal wiring 530 to the contact plug 520. At the farthest point from the peripheral circuit region PER among the core region COR positioned on the right side of the peripheral circuit region PER, the distance from the left-side edge of the core signal wiring 530 to the contact plug 520 may be greater than the distance from the right-side edge of the core signal wiring 530 to the contact plug 520. At the center point between the closest point to the peripheral circuit region PER and the farthest point from the peripheral circuit region PER among the core region COR positioned on the right side of the peripheral circuit region PER, the distance from the left-side edge of the core signal wiring 530 to the contact plug 520 and the distance from the right-side edge of the core signal wiring 530 to the contact plug 520 may be substantially the same.

As for the core region COR positioned on the left side of the peripheral circuit region PER, the distance from the right-side edge of the core signal wiring 530 to the contact plug 520 may gradually increase as a distance from the peripheral circuit region PER increases. In addition, the distance from the left-side edge of the core signal wiring 530 to the contact plug 520 may gradually decrease as a distance from the peripheral circuit region PER increases. At the closest point to the peripheral circuit region PER among the core region COR positioned on the left side of the peripheral circuit region PER, the distance from the right-side edge of the core signal wiring 530 to the contact plug 520 may be smaller than the distance from the left-side edge of the core signal wiring 530 to the contact plug 520. At the farthest point from the peripheral circuit region PER among the core region COR positioned on the left side of the peripheral circuit region PER, the distance from the right-side edge of the core signal wiring 530 to the contact plug 520 may be greater than the distance from the left-side edge of the core signal wiring 530 to the contact plug 520. At the center point between the closest point to the peripheral circuit region PER and the farthest point from the peripheral circuit region PER among the core region COR positioned on the left side of the peripheral circuit region PER, the distance from the right-side edge of the core signal wiring 530 to the contact plug 520 and the distance from the left-side edge of the core signal wiring 530 to the contact plug 520 may be substantially the same.

A semiconductor device according to an embodiment may be formed through several patterning processes. One wafer may include a plurality of semiconductor chips, and the plurality of semiconductor chips may have similar patterns. Each semiconductor chip may include the cell array region CAR, the core region COR, and the peripheral circuit region PER. Each patterning process is performed on the entire wafer, and the patterns included in each semiconductor chip may be formed simultaneously. In addition, patterns may be simultaneously formed in the cell array region CAR, the core region COR, and the peripheral circuit region PER. At this time, the patterns may not be evenly distributed in the cell array region CAR, the core region COR, and the peripheral circuit region PER. For example, a relatively small amount of patterns may be formed in the peripheral circuit region PER compared to the cell array region CAR and the core region COR. In the step of forming the pad metal pattern 159 of the landing pad LP in the cell array region CAR and forming the core circuit wiring 510 in the core area COR, relatively little amount of patterns may be formed in the peripheral circuit region PER. Positive patterns. Differences in the density of these patterns may affect the distribution of etchant during the patterning process, and may cause differences between the designed pattern and the actually formed pattern. Accordingly, contact failure with a formed in a subsequent process may occur, and in an embodiment, contact failure between patterns positioned on different layers may be limited and/or prevented by changing the pattern to compensate for this difference.

A semiconductor device according to a reference example in which contact failure occurs due to differences between the designed pattern and the actually formed pattern will be described as follows.

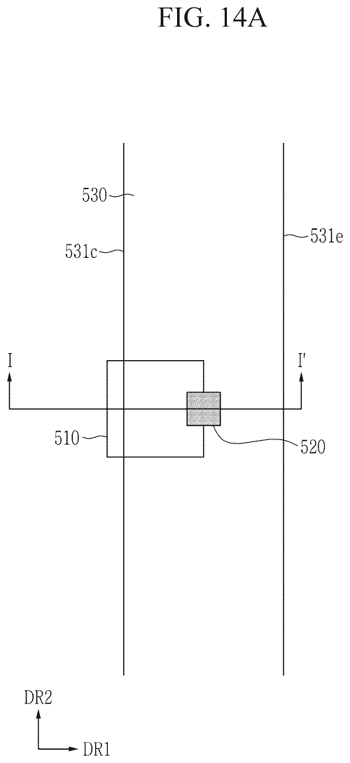

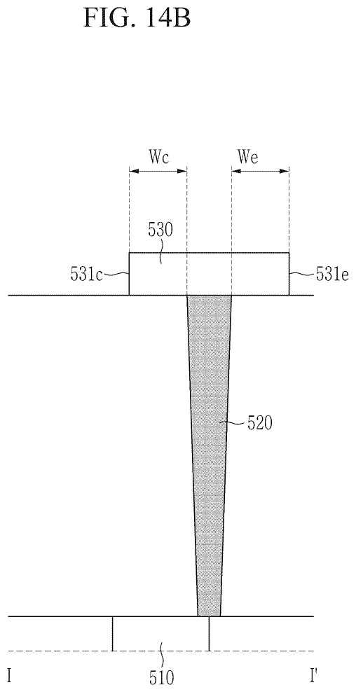

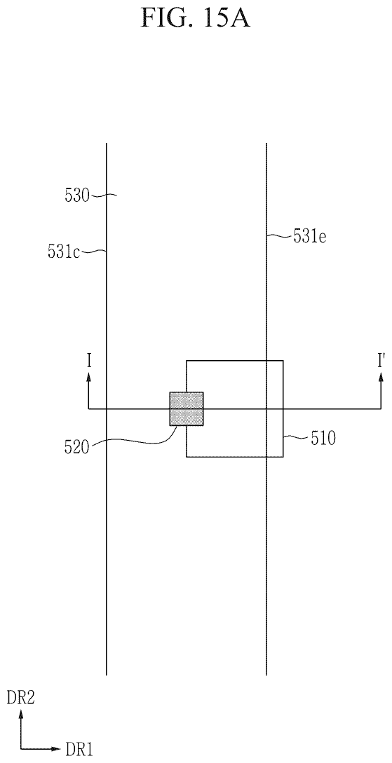

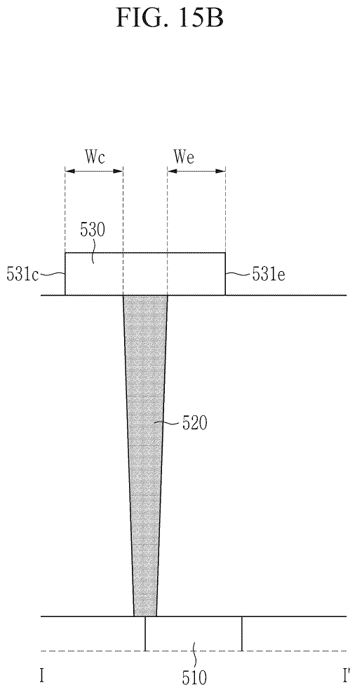

FIG. 14A to FIG. 15B are enlarged plan views or cross-sectional views showing of partial regions of a semiconductor device according to reference example. FIG. 14A and FIG. 15A are top plan views. FIG. 14B and FIG. 15B are cross-sectional views. FIG. 14A is a top plan view showing a portion of the core region COR positioned at the closest point to the peripheral circuit region PER, in the right side of the peripheral circuit region PER. FIG. 14B is a cross-sectional view along line I-I′ of FIG. 14A. FIG. 15A is a top plan view showing a portion of the core region COR positioned at the farthest point from the peripheral circuit region PER, in the right side of the peripheral circuit region PER. FIG. 15B is a cross-sectional view along line I-I′ of FIG. 15A.

In a semiconductor device according to reference example, regardless of the distance from the peripheral circuit region PER, the positional relationship between the core signal wiring 530 and the contact plug 520 may be constant. For example, regardless of the distance from the peripheral circuit region PER, the first distance Wc and the second distance We may be constant. Regardless of the distance from the peripheral circuit region PER, the first distance Wc and the second distance We may be the same. The contact plug 520 may overlap a central portion of the core signal wiring 530.

The contact plug 520 may be designed to overlap the central portion of the core circuit wiring 510, and overlap the central portion of the core signal wiring 530. At this time, a position of the core circuit wiring 510 may be shifted during the process.

As shown in FIG. 14A and FIG. 14B, at the point close to the peripheral circuit region PER among the core region COR positioned on the right side of the peripheral circuit region PER, the position of the core circuit wiring 510 may be shifted to the left. Accordingly, the contact plug 520 may not overlap the central portion of the core circuit wiring 510, and may overlap a right-side end portion of the core circuit wiring 510. Accordingly, contact resistance between the contact plug 520 and the core circuit wiring 510 may increase, and contact failure may occur. When the core circuit wiring 510 is further shifted to the left than illustrated, the contact plug 520 and the core circuit wiring 510 may not be connected.

As shown in FIG. 15A and FIG. 15B, at the point far from the peripheral circuit region PER among the core region COR positioned on the right side of the peripheral circuit region PER, the position of the core circuit wiring 510 may be shifted to the right. Accordingly, the contact plug 520 may not overlap the central portion of the core circuit wiring 510, and may overlap a left-side end portion of the core circuit wiring 510. Accordingly, contact resistance between the contact plug 520 and the core circuit wiring 510 may increase, and contact failure may occur. When the core circuit wiring 510 is further shifted to the right than illustrated, the contact plug 520 and the core circuit wiring 510 may not be connected.

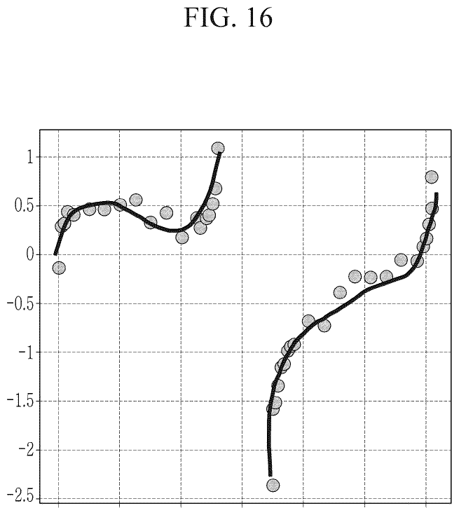

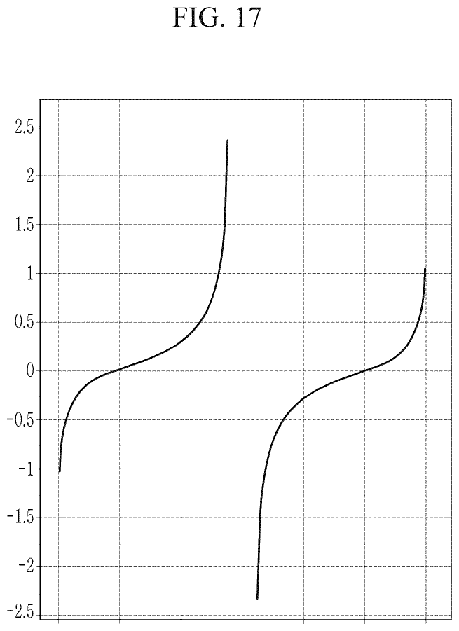

Hereinafter, referring to FIG. 16 and FIG. 17, the tendency that the core circuit wiring and the contact plug are misaligned by the shifting of the core circuit wiring in a semiconductor device according to reference example will be described as follows.

FIG. 16 and FIG. 17 is a graph showing misalignment trends between a core circuit wiring and a contact plug in a semiconductor device according to reference example. FIG. 16 is a graph based on data obtained through experiment. FIG. 17 is a theoretical graph compensated in consideration of various errors affecting the experiment. The horizontal axis represents a distance from a left-side edge of a semiconductor chip, a central portion of the horizontal axis may correspond to the peripheral circuit region positioned in the central portion of the semiconductor chip. The vertical axis represents the level of misalignment between the core circuit wiring and the contact plug, in which a minus (negative) direction may represent a case that the core circuit wiring is shifted to the left and misaligned with the contact plug, and a plus (positive) direction may represent a case that the core circuit wiring is shifted to the right and misaligned with the contact plug.

As shown in FIG. 16 and FIG. 17, the shifting of core circuit wiring may occur largest at the point close to the peripheral circuit region, and there may be a tendency that the shifted level of the core circuit wiring decreases away from the peripheral circuit region and then increases again. Hereinafter, the description will be made mainly with reference to the graph of FIG. 17 in which the error has been corrected. In the core region positioned on the right side of the peripheral circuit region, the core circuit wiring may be shifted to the left at the point close to the peripheral circuit region, and there may be a tendency that the shifted level of the core circuit wiring decreases away from the peripheral circuit region and then is shifted to the right. In the core region positioned on the left side of the peripheral circuit region, the core circuit wiring may be shifted to the right at the point close to the peripheral circuit region, and there may be a tendency that the shifted level of the core circuit wiring decreases away from the peripheral circuit region and then is shifted to the left.

According to this tendency, the positional relationship between the core signal wiring and the contact plug may be designed to be corrected differently depending on distance from the peripheral circuit region. In addition, the positional relationship between the core signal wiring and the contact plug in the core region positioned on the left side of the peripheral circuit region may be designed to be symmetrical to the positional relationship between the core signal wiring and the contact plug in the core region positioned on the right side of the peripheral circuit region. However, the positional relationship between the core signal wiring and the contact plug in the core region positioned on the left side of the peripheral circuit region may not be in a perfect symmetry with the positional relationship between the core signal wiring and the contact plug in the core region positioned on the right side of the peripheral circuit region. That is, a substantial symmetry within an error range may be formed.

The point where the misalignment level between the core circuit wiring and the contact plug is 0 may not be a center point between the closest point to the peripheral circuit region and the farthest point from the peripheral circuit region. For example, in the core region positioned on the right side of the peripheral circuit region, the point where the misalignment level between the core circuit wiring and the contact plug is 0 may be positioned further to the right than the center point between the closest point to the peripheral circuit region and the farthest point from the peripheral circuit region. In the core region positioned on the left side of the peripheral circuit region, the point where the misalignment level between the core circuit wiring and the contact plug is 0 may be positioned further to the left than the center point between the closest point to the peripheral circuit region and the farthest point from the peripheral circuit region. The positional relationship between the core signal wiring and the contact plug may be designed to be appropriately altered in consideration of these characteristics.

While this disclosure has been described in connection with what is presently considered to be practical embodiments, it is to be understood that inventive concepts are not limited to the disclosed embodiments, but, on the contrary, are intended to cover various modifications and equivalent arrangements included within the spirit and scope of the appended claims.

### DESCRIPTION OF SYMBOLS

100: substrate
CAR: cell array region
COR: core region
PER: peripheral circuit region
510: core circuit wiring
520: contact plug
530: core signal wiring

What is claimed is:

1. A semiconductor device, comprising:
a substrate including a cell array region, a core region, and a peripheral circuit region;
a core circuit wiring on the core region of the substrate;
a core signal wiring overlapping the core circuit wiring; and
a contact plug between the core circuit wiring and the core signal wiring and connecting the core circuit wiring to the core signal wiring, wherein
a positional relationship between the core signal wiring and the contact plug is different depending on a distance of the contact plug from the peripheral circuit region.

2. The semiconductor device of claim 1, wherein
the core signal wiring comprises a first edge and a second edge opposite the first edge;
the first edge is closer to the peripheral circuit region than the second edge;
a first distance from the first edge of the core signal wiring to the contact plug gradually increases as the distance of contact plug from the peripheral circuit region increases.

3. The semiconductor device of claim 2, wherein a second distance from the second edge of the core signal wiring to the contact plug gradually decreases as the distance of the contact plug from the peripheral circuit region increases.

4. The semiconductor device of claim 3, wherein
the first distance is smaller than the second distance at a closest point to the peripheral circuit region;
the first distance is greater than the second distance at a farthest point from the peripheral circuit region; and
the first distance and the second distance are equal at a center point between the closest point to the peripheral circuit region and the farthest point from the peripheral circuit region.

5. The semiconductor device of claim 1, wherein
the substrate includes a plurality of cell array regions arranged along a first direction and a second direction at both sides of the peripheral circuit region,
the core region is between the plurality of cell array regions, and
the positional relationship between the core signal wiring and the contact plug in the core region positioned on a left side of the peripheral circuit region is symmetrical to the positional relationship between the core signal wiring and the contact plug in the core region positioned on a right side of the peripheral circuit region.

6. The semiconductor device of claim 5, wherein
the peripheral circuit region extends along the second direction,
the plurality of cell array regions and the core region are positioned on the both sides of the peripheral circuit region along the first direction.

7. The semiconductor device of claim 6, wherein
in an area of the core region positioned on the right side of the peripheral circuit region,
a distance from a left-side edge of the core signal wiring to the contact plug gradually increases as the distance of the contact plug from the peripheral circuit region increases, and
a distance from a right-side edge of the core signal wiring to the contact plug gradually decreases as the distance of the contact plug from the peripheral circuit region increases.

8. The semiconductor device of claim 7, wherein
at a closest point to the peripheral circuit region in the area of the core region positioned on the right side of the peripheral circuit region, the distance from the left-side edge of the core signal wiring to the contact plug is smaller than the distance from the right-side edge of the core signal wiring to the contact plug, and
at a farthest point from the peripheral circuit region in the area of the core region positioned on the right side of the peripheral circuit region, the distance from the left-side edge of the core signal wiring to the contact plug is greater than the distance from the right-side edge of the core signal wiring to the contact plug.

9. The semiconductor device of claim 6, wherein
in an area of the core region positioned on the left side of the peripheral circuit region,
a distance from a right-side edge of the core signal wiring to the contact plug gradually increases as the distance of the contact plug from the peripheral circuit region increases, and
a distance from a left-side edge of the core signal wiring to the contact plug gradually decreases as the distance of the contact plug from the peripheral circuit region increases.

10. The semiconductor device of claim 9, wherein
at a closest point to the peripheral circuit region among the area of the core region positioned on the left side of the peripheral circuit region, the distance from the left-side edge of the core signal wiring to the contact plug is greater than the distance from the right-side edge of the core signal wiring to the contact plug; and
at a farthest point from the peripheral circuit region among the core regions positioned on the right side of the peripheral circuit region, the distance from the left-side edge of the core signal wiring to the contact plug is smaller than the distance from the right-side edge of the core signal wiring to the contact plug.

11. The semiconductor device of claim 1, wherein a positional relationship between the core circuit wiring and the contact plug is constant regardless of the distance of the contact plug from the peripheral circuit region.

12. The semiconductor device of claim 1, further comprising:
a word line on the cell array region of the substrate;
a bit line crossing the word line;
a bit line contact pattern connecting between a first active region of the substrate and the bit line;
a landing pad connected to the first active region of the substrate; and
a lower contact between the landing pad and the first active region of the substrate an connecting the landing pad to the first active region, wherein
the core circuit wiring is in a same layer as the landing pad.

13. The semiconductor device of claim 12, further comprising:
an insulating layer on the substrate;
a capacitor connected to the landing pad;
a cell signal wiring connected to the capacitor; and
a capacitor contact via between the capacitor and the cell signal wiring and connecting the capacitor to the cell signal wiring, wherein
a level of the core signal wiring above the substrate is in the same as a level of the cell signal wiring above the substrate, and
the contact plug and the capacitor contact via each extend through the insulating layer.

14. The semiconductor device of claim 1, further comprising:
a gate stack on the core region of the substrate, wherein
the substrate includes an impurity region positioned at both sides of the gate stack, and
the core circuit wiring is connected to the impurity region.

15. A semiconductor device, comprising:
a substrate including a peripheral circuit region, a plurality of cell array regions at both sides of the peripheral circuit region and arranged along a first direction and a second direction, and a core region between the plurality of cell array regions;
a core circuit wiring on the core region of the substrate;
a core signal wiring overlapping the core circuit wiring; and
a contact plug between the core circuit wiring and the core signal wiring and connecting the core circuit wiring to the core signal wiring, wherein
a first distance from a first edge of the core signal wiring to the contact plug gradually changes as a distance of the contact plug from the peripheral circuit region increases.

16. The semiconductor device of claim 15, wherein
the core signal wiring comprises a second edge opposite the first edge;
the first edge is closer to the peripheral circuit region than the second edge;
the first distance from the first edge of the core signal wiring to the contact plug gradually increases as the distance of the contact plug from the peripheral circuit region increases.

17. The semiconductor device of claim 16, wherein a second distance from the second edge of the core signal wiring to the contact plug gradually decreases as the distance of the contact plug from the peripheral circuit region increases.

18. The semiconductor device of claim 15, wherein a positional relationship between the core circuit wiring and the contact plug is constant regardless of a distance from the peripheral circuit region.

19. A semiconductor device, comprising:
a substrate including a cell array region, a core region, and a peripheral circuit region;
a memory cell on the cell array region of the substrate;
a gate stack on the core region of the substrate, the substrate including an impurity region positioned at both sides of the gate stack;
a core circuit wiring connected to the impurity region;
an insulation layer positioned on the core circuit wiring;
a core signal wiring on the insulation layer; and
a contact plug penetrating the insulation layer and between the core circuit wiring and the core signal wiring, wherein
the contact plug connects the core circuiting wiring to the core signal wiring, and
a positional relationship between the core signal wiring and the contact plug is different depending on a distance of the contact plug from the peripheral circuit region.

20. The semiconductor device of claim 19, wherein
the core signal wiring comprises a first edge and a second edge opposite each other;
the first edge is closer to the peripheral circuit region than the second edge; and
a first distance from the first edge of the core signal wiring to the contact plug gradually increases as the distance of the contact plug from the peripheral circuit region increases.
